(19) United States
(12) Patent Application Publication
(10) Pub. No.: US 2016/0011248 A1
(43) Pub. Date: Jan. 14, 2016

(54) CRYSTAL UNIT AND DEVICE FOR MEASURING CHARACTERISTICS OF THE CRYSTAL UNIT

(71) Applicant: FUJITSU LIMITED, Kawasaki-shi (JP)

(72) Inventors: Masakazu Kishi, Kawasaki (JP); Masaru ITOH, Kawasaki (JP); Masayuki ITOH, Kawasaki (JP)

(21) Appl. No.: 14/737,783

(22) Filed: Jun. 12, 2015

(30) Foreign Application Priority Data
Jul. 10, 2014 (JP) 2014-142396

(51) Int. Cl. G01R 31/00; H03H 9/17; G01R 23/00; H01L 41/047

(52) U.S. Cl. CPC G01R 31/00; H01L 41/0477; H03H 9/17; G01R 23/00

(57) ABSTRACT

A crystal unit includes: a crystal piece; a first excitation electrode disposed on a first surface of the crystal piece and made of non-magnetic material; and a second excitation electrode disposed on a second surface in the opposite side to the first surface in the crystal piece facing the first excitation electrode, and made of magnetic material, the second excitation electrode includes a first magnetic portion and a second magnetic portion closer to the center of the crystal piece than the first magnetic portion, wherein the second magnetic portion is larger than the first magnetic portion in terms of at least one of thickness, density and permeability.

### CROSS-REFERENCE TO RELATED APPLICATION

This application is based upon and claims the benefit of priority of the prior Japanese Patent Application No. 2014-142396 filed on Jul. 10, 2014, the entire contents of which are incorporated herein by reference.

### FIELD

The embodiments discussed herein are related to a crystal unit and a device for measuring characteristics of the crystal unit.

### BACKGROUND

There has been known a technique for constructing a crystal oscillation element by forming an electrode film made of only ferromagnetic material on one side of a crystal oscillating piece (oscillation element) so that the crystal oscillation element may be adsorbed in and held by a magnetic force of a probe.

In recent years, compactness and high density mounting of parts and modules have progressed to meet the demands for device downsizing. Compactness of crystal units serving as clock sources has been also unexceptionally progressed. Under such circumstances, when the functional failure of a device is deemed to have occurred due to the abnormality of a crystal unit, it is useful to be able to measure electrical characteristics of the crystal unit with it mounted in the device. This is because it is difficult to take out only the crystal unit for measurement from reasons such as destroys of peripheral components when removing the crystal unit mounted with a high density.

In this regard, in the mounted state of the crystal unit, it may be possible to make a probe measurement of high impedance. However, with the recent downsizing trends, there may be a case where no probing point is present, such as, for example, an IC (Integrated Circuit) having no terminal which can verify an oscillation state, and a crystal unit having a provision of terminals in the backside. Moreover, with the progress of a high density mounting, there may be a case where there is no site that a probe may contact physically. In addition, even when a probing point is present, there may be a case where an oscillation state is changed by only a few pF capacitance applied by a probe, thereby making a correct measurement impossible.

The following is a reference document.

[Document 1] Japanese Laid-open Patent Publication No. 2008-271331.

### SUMMARY

According to an aspect of the invention, a crystal unit includes: a crystal piece; a first excitation electrode disposed on a first surface of the crystal piece and made of non-magnetic material; and a second excitation electrode disposed on a second surface in the opposite side to the first surface in the crystal piece facing the first excitation electrode, and made of magnetic material, the second excitation electrode includes a first magnetic portion and a second magnetic portion closer to the center of the crystal piece than the first magnetic portion, wherein the second magnetic portion is larger than the first magnetic portion in terms of at least one of thickness, density and permeability.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B are schematic views illustrating a crystal unit 100 according to one example (Embodiment 1);

FIG. 2 is a schematic view illustrating a characteristic measuring device 300 according to the crystal unit 100;

FIG. 3 is an explanatory view of the principle of generation of an AC waveform;

FIG. 4 is a schematic view illustrating one example of a circuit configuration incorporating the crystal unit 100;

FIG. 5 is a view illustrating one example of a mounted state of the crystal unit 100;

FIG. 6 is an explanatory view of one example of an upper excitation electrode 21;

FIG. 7 is an explanatory view of another example of the upper excitation electrode 21;

FIGS. 8A and 8B are explanatory views of another example of the upper excitation electrode 21;

FIG. 9 is a schematic sectional view illustrating a crystal unit 102 according to one example (Embodiment 2);

FIG. 10 is a schematic view illustrating a characteristic measuring device 302 according to the crystal unit 102;

FIG. 11 is an explanatory view of the principle of generation of an AC waveform;

FIG. 12 is an explanatory view of one example of an upper excitation electrode 21A; and

FIG. 13 is an explanatory view of another example of the upper excitation electrode 21A.

### DESCRIPTION OF EMBODIMENTS

Hereinafter, embodiments will be described in detail with reference to the accompanying drawings.

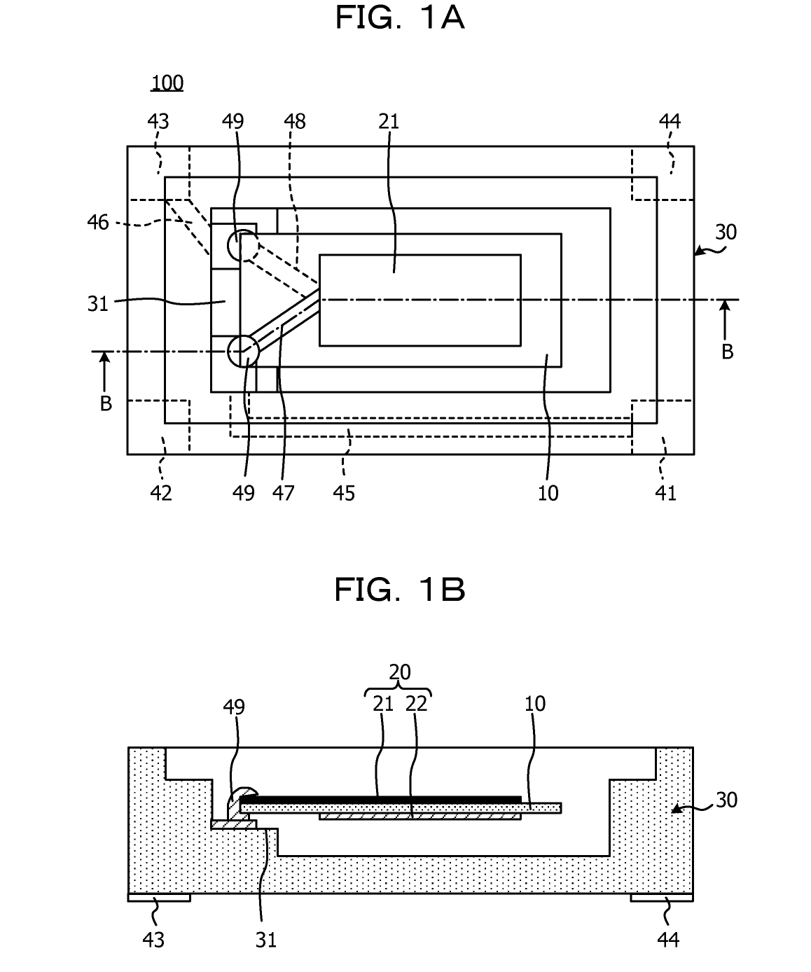

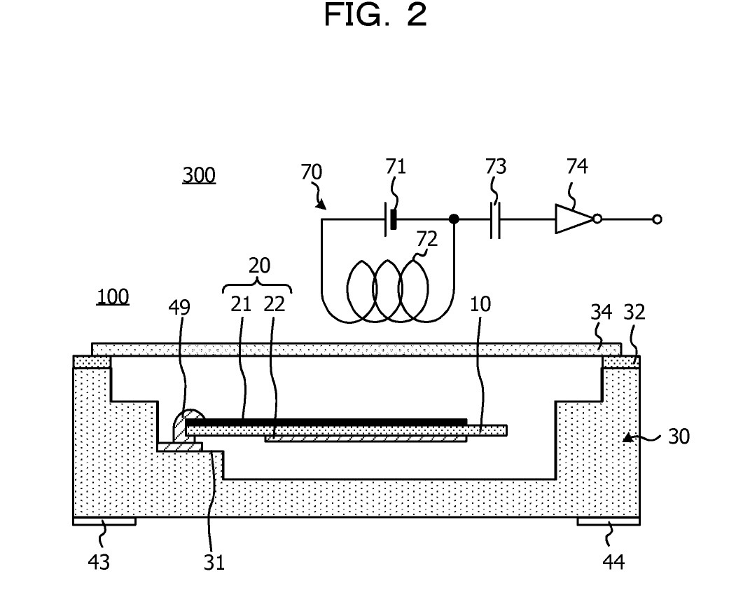

FIGS. 1A and 1B are schematic views illustrating a crystal unit 100 according to one example (Embodiment 1), FIG. 1A being a top view and FIG. 1B being a sectional view taken along line B-B in FIG. 1A. In FIG. 1A, a cover of a case 30 is not illustrated to allow the interior of the crystal unit 100 to be viewed. In the following description, for the convenience of description, it is assumed that a thickness direction of a crystal piece 10 (a vertical direction in FIG. 1B) is a vertical direction and a side in which the cover of the case 300 is present is an “upper side.” However, a direction of a mounted state of the crystal unit 100 is optional. FIG. 2 is a schematic view illustrating a characteristic measuring device 300 according to the crystal unit 100.

The crystal unit 100 includes a crystal piece 10, an excitation electrode 20, a case 30 and external electrodes 41 to 44. The crystal unit 100 is of a surface mounting type as illustrated in FIGS. 1A and 1B.

The crystal piece 10 may be, for example, an AT cut synthetic crystal substrate. The crystal piece 10 may be supported in a cantilever structure to the case 30. In the example illustrated in FIGS. 1A and 1B, the crystal piece 10 is supported in the cantilever structure on a dam portion 31 of the case 30.

The excitation electrode 20 excites the crystal piece 10. The excitation electrode 10 includes an upper excitation electrode (one example of a magnetic material portion) 21 formed on the upper surface of the crystal piece 10 and a lower excitation electrode 22 formed on the lower surface of the crystal piece 10. The excitation electrode 20 excites the crystal piece 10 using a potential difference between the upper excitation electrode 21 and the lower excitation electrode 22.

The upper excitation electrode 21 is made of conductive magnetic material. The upper excitation electrode 21 may also be made of, for example, iron, nickel, or cobalt. The upper excitation electrode 21 may be formed in a film shape. The configuration of the upper excitation electrode 21 will be described later by way of several examples.

The lower excitation electrode 22 is made of non-magnetic material. For example, the lower excitation electrode 22 may be made of, for example, gold, silver, or aluminum.

The case 30 accommodates the crystal piece 10. The case 30 is made of ceramic material. The case 30 includes a cover 34 (see, e.g., FIG. 2) and air-tightly seals the crystal piece 10 in its internal space. For example, the internal space of the case 30 is vacuous or filled with dry nitrogen, and is sealed with the cover 34 and a sealant 32 (see, e.g., FIG. 2). The cover 34 may be a metal plate or a ceramic plate.

The external electrodes 41 to 44 are formed in the case 30. In the example illustrated in FIGS. 1A and 1B, the external electrodes 41 to 44 are formed on the outer surface of the bottom of the case 30. The external electrodes 41 and 43 are electrically connected to the upper excitation electrode 21 and the lower excitation electrode 22, respectively. In the example illustrated in FIGS. 1A and 1B, the external electrode 41 is electrically connected to the upper excitation electrode 21 via a conductor pattern 45 formed on an inner layer of the case 30 and a conductor pattern 47 formed on the upper surface of the crystal piece 10. The conductor pattern 45 has both ends exposed from the inner layer to the surface of the case 30, with one end electrically connected to the external electrode 41 and the other end electrically connected to the conductor pattern 47 by a conductive adhesive 49.

Similarly, the external electrode 43 is electrically connected to the lower excitation electrode 22 via a conductor pattern 46 formed on the inner layer of the case 30 and a conductor pattern 48 formed on the lower surface of the crystal piece 10. The conductor pattern 46 has both ends exposed from the inner layer to the surface of the case 30, with one end electrically connected to the external electrode 43 and the other end electrically connected to the conductor pattern 48 by the conductive adhesive 49. The conductive adhesive 49 is formed at an edge of the crystal piece 10 (an edge of a cantilever-supported side). In the example illustrated in FIGS. 1A and 1B, the external electrodes 42 and 44 may be omitted.

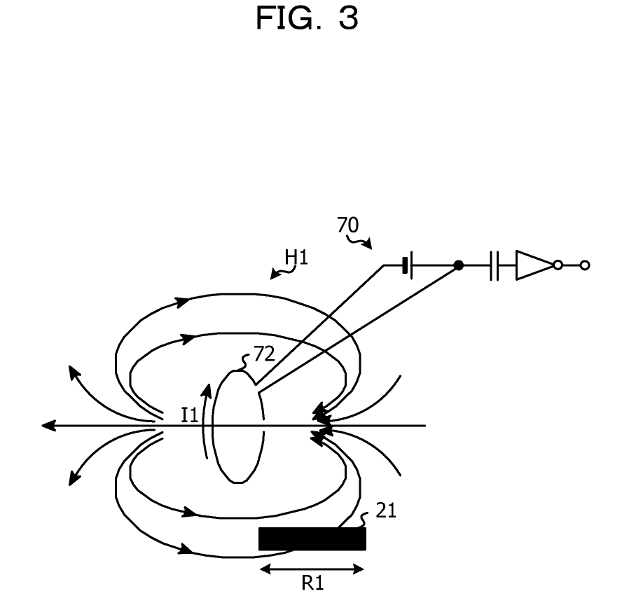

In operation of the crystal unit 100, when the crystal piece 10 is oscillated at a certain frequency, the upper excitation electrode 21 is vibrated at that frequency. At this time, as illustrated in FIG. 2, an AC waveform of a frequency corresponding to the oscillation frequency of the crystal piece 10 is generated in a receiving coil 70 disposed over the cover 34, due to the vibration of the upper excitation electrode 21. More specifically, in the example illustrated in FIG. 2, the receiving coil 70 is an electromagnet and, when a current is flown into the receiving coil 70, a magnetic field H1 is formed by a coil portion 72, as schematically illustrated in FIG. 3.

At this time, as schematically illustrated in FIG. 3, when the upper excitation electrode 21 is vibrated (see an arrow R1), the magnetic field H1 is affected by the vibration of the upper excitation electrode 21 which is a magnetic material. That is, a magnetic flux is changed in accordance with the vibration of the upper excitation electrode 21 which is the magnetic material and an electromotive force is generated in the coil portion 72 in a counter-wise way. As a result, the AC waveform of the frequency corresponding to the oscillation frequency of the crystal piece 10 is superimposed on a current I1 flown into the coil portion 72. Accordingly, as schematically illustrated in FIG. 2, by forming the receiving coil 70 in the outside of the crystal unit 100, it is possible to generate this AC waveform in the receiving coil 70 and measure the oscillation frequency of the crystal unit 100.

Hereinafter, the function to generate the AC waveform in the receiving coil 70 is also referred to as the function of transmission of oscillation frequency information to the outside. In addition, in the example illustrated in FIG. 2, a DC component of a received signal including the AC waveform generated in the coil portion 72 is cut by a capacitor 73 and an AC component thereof is amplified by an amplifier 74. Based on the amplified AC component, a frequency (the oscillation frequency of the crystal unit 100) is measured (analyzed) by a measuring device such as, for example, an oscilloscope (not illustrated).

With the crystal unit 100 illustrated in FIGS. 1A and 1B, when the upper excitation electrode 21 of the crystal unit 100 is made of magnetic material, the oscillation frequency of the crystal unit 100 may be externally measured. Thus, for example, for the crystal unit 100 in the mounted state, it is possible to measure the oscillation frequency with the crystal unit 100 mounted in the device. As the oscillation frequency may be measured, it becomes possible to make a comparison of relative characteristics with non-defective products.

In the crystal unit 100, the upper excitation electrode 21 is made of conductive magnetic material and the lower excitation electrode 22 is made of non-magnetic material. This is because, for an AT cut type, the upper excitation electrode 21 and the lower excitation electrode 22 are opposite to each other in the vibration direction (e.g., vibrated in the reverse phase) and if the lower excitation electrode 22 is made of magnetic material, the AC waveform as described above is not formed in the receiving coil 70.

In the example illustrated in FIG. 2, in the characteristic measurement, although the receiving coil 70 is disposed above the cover 34, the receiving coil 70 may be disposed at any positions as long as the magnetic field H1 is affected by the vibration of the upper excitation electrode 21. For example, the receiving coil 70 may be disposed relative to the crystal unit 100 such that the upper excitation electrode 21 is located on or near the central axis of the coil portion 72.

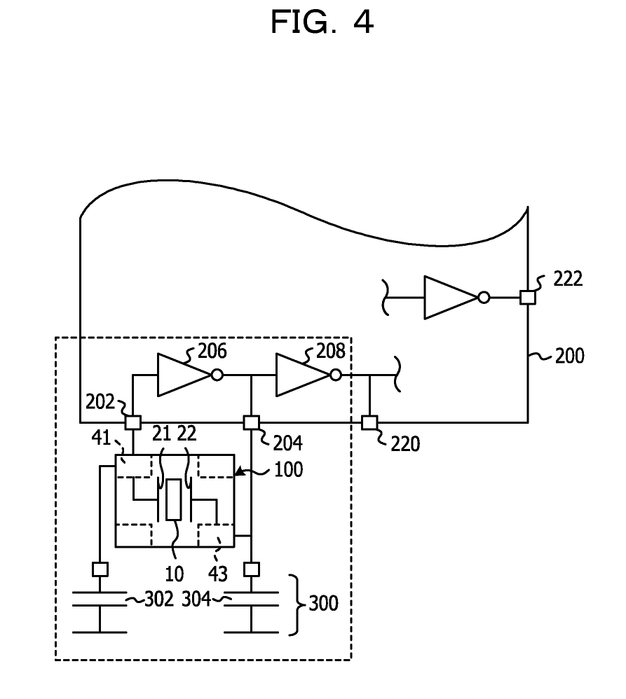

FIG. 4 is a schematic view illustrating one example of a circuit configuration incorporating the crystal unit 100.

In the example illustrated in FIG. 4, the crystal unit 100 is connected to an IC 200. That is, the external electrodes 41 and 43 of the crystal unit 100 are respectively connected to an input terminal 202 and an output terminal 204 of the IC 200. The crystal unit 100 generates a clock used in the IC 200. The IC 200 includes an inverting amplifier 206 and an output buffer 208. A signal input to the input terminal 202 is inverted and amplified by the inverting amplifier 206. The inverted and amplified signal is input to the output buffer 208 and is supplied to the upper excitation electrode 21 via the external electrode 43. In the example illustrated in FIG. 4, the upper excitation electrode 21 and the lower excitation electrode 22 may be reversed.

Matching capacitors 300 are connected to the crystal unit 100. More specifically, a first capacitor 302 is connected between the external electrode 41 of the crystal unit 100 and a ground, and a second capacitor 304 is connected between the external electrode 43 of the crystal unit 100 and the ground. With regard to the IC 200, for example, a terminal internal capacitance, a stray capacitance of wiring patterns of a mounting substrate, and a resistance limiting a current flown into the crystal unit 100 are not illustrated in FIG. 4. The matching capacitors 300 are formed to adjust the oscillation frequency of the crystal unit 100 such that the oscillation frequency becomes a desired value (designed value) when the total capacitance (load capacitance) including all circuit capacitance ranging from the crystal unit 100 to the IC 200 is assumed as a load. In FIG. 4, the range enclosed by a dotted line forms an oscillation circuit.

The IC 200 may include terminals 220 and 222 for monitoring the oscillation circuit. However, these terminals 220 and 222 may be omitted. This is because the oscillation frequency of the crystal unit 100 may be measured (monitored) by the function of transmission of oscillation frequency information to the outside, which is included in the crystal unit 100, as described above. Accordingly, the crystal unit 100 illustrated in FIGS. 1A and 1B eliminates a need to form the terminals 220 and 222, thereby simplifying the IC 200.

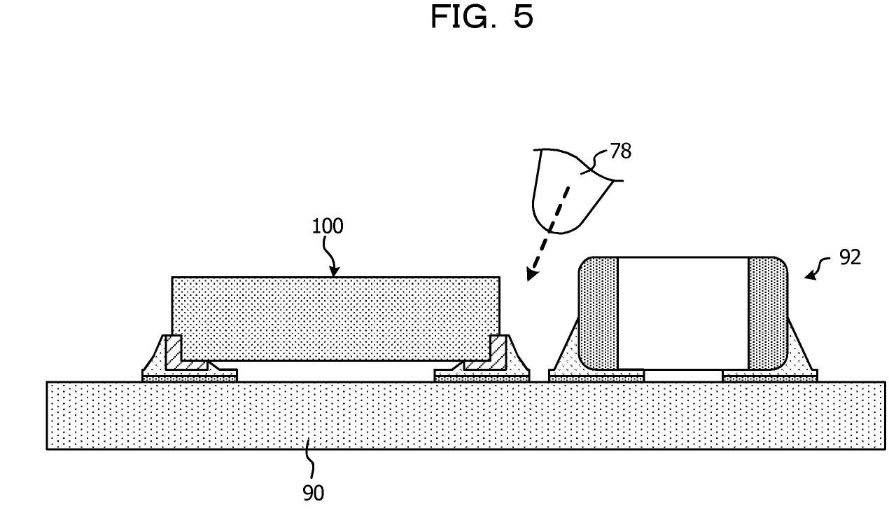

FIG. 5 is a view illustrating one example of a mounted state of the crystal unit 100.

As illustrated in FIG. 5, the crystal unit 100 may be mounted on a substrate 90. In the example illustrated in FIG. 5, a peripheral component 92 is mounted near the crystal unit 100.

In the meantime, in recent years, compactness and a high density mounting of parts and modules have been progressed to meet the demands for downsizing the device. The compactness (e.g., 3.2×2.5 mm, 2.5×2.0 mm and 2.0×1.6 mm) of the crystal units serving as clock sources has been also unexceptionally progressed. Under such circumstances, when the functional failure of a device is deemed to have occurred due to the abnormality of a crystal unit, it is useful to be able to measure the electrical characteristics of the crystal unit with it mounted in the device. This is because taking out only the crystal unit mounted with high density for a measurement is accompanied by a risk of destroying peripheral components when removing the crystal unit.

In this regard, in the mounted state of the crystal unit, it may be possible to make a probe measurement of high impedance. However, with the recent trends of downsizing, there may be a case where the IC 200 does not have a terminal which may verify an oscillation state (see, e.g., the terminals 220 and 222 in FIG. 4) and terminals are hidden in the back side of an IC package by the BGA (Ball Grid Array). In addition, there may be a case where no probing point is present, such as, for example, the matching capacitors 300 being incorporated in the IC 200, and a provision of terminals in the backside of the crystal unit 100. In addition, with progress of high density mounting, there may be a case where there is no site that the probe 78 contacts physically, as schematically illustrated in FIG. 5. In addition, even when a probing point is present, if the margin of design of an oscillation circuit is insufficient, there may be a case where an oscillation state is changed (from a oscillation state to a non-oscillation state and vice versa) by only a few pF capacitance applied by the probe 78, making a correct measurement impossible.

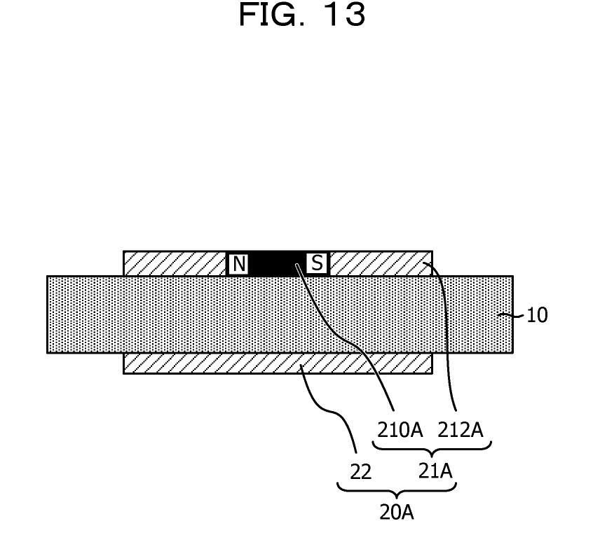

In this regard, with the crystal unit 100 illustrated in FIGS. 1A and 13, since the upper excitation electrode 21 of the crystal unit 100 is made of magnetic material as described above, the oscillation frequency of the crystal unit 100 may be precisely measured even when the probe measurement is impossible or difficult.

Next, several configuration examples of the upper excitation electrode 21 will be described.

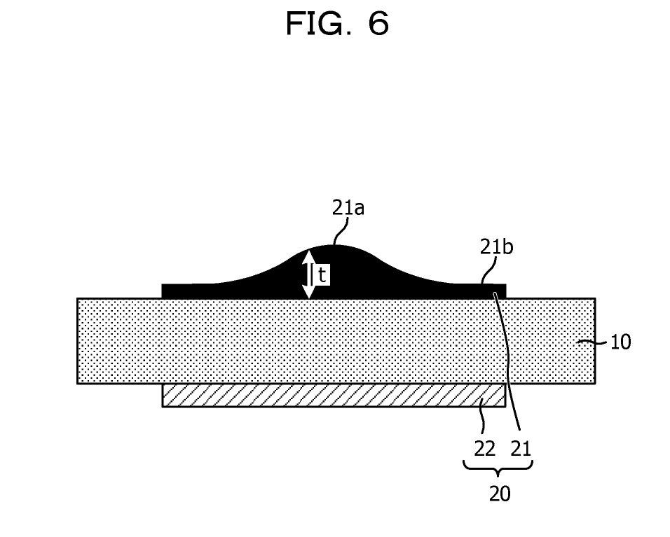

FIG. 6 is an explanatory view of one example of the upper excitation electrode 21, illustrating a sectional view of the upper excitation electrode 21, the crystal piece 10 and the lower excitation electrode 22. A cut section of the sectional view of FIG. 6 passes through the geometrical center (or the center of gravity) of the upper excitation electrode 21 when viewed from the top. For example, the cut section of the sectional view of FIG. 6 may be a vertical plane passing through the geometrical center of the upper excitation electrode 21 when viewed from the top.

In the example illustrated in FIG. 6, the upper excitation electrode 21 includes a first magnetic portion 21b and a second magnetic portion 21a which is closer to the center side of the crystal piece 10 than the first magnetic portion 21b. The second magnetic portion 21a is thicker than the first magnetic portion 21b. That is, in the example illustrated in FIG. 6, the upper excitation electrode 21 has thickness t (a film thickness) larger in the central region than the outer region. The characteristics of this thickness may be characteristics corresponding to any section passing though the center of the upper excitation electrode 21. An aspect of change in the thickness t may be a smooth change aspect as illustrated in FIG. 6, or may be accompanied by a step.

The thickness t of each position in the upper excitation electrode 21 may be determined in such a manner to be proportional to vibration energy at a corresponding position of the crystal piece 10 (that is, a portion of the crystal piece 10 immediately below it). In an embodiment, the thickness of the upper excitation electrode 21 at a plurality of positions along a direction perpendicular to the thickness direction of the crystal piece 10 is proportional to the vibration energy in oscillation at each corresponding position of the crystal piece 10. Since the crystal piece 10 is generally more deformed (vibrated) in the central portion having a high charge density than the peripheral portions, the vibration energy of the crystal piece 10 is higher in the central portion than the peripheral portions. The vibration energy of the crystal piece 10 has a distribution close to the Gaussian distribution although it depends on a percentage of occupation of the upper excitation electrode 21 or a shape thereof.

According to the example illustrated in FIG. 6, the upper excitation electrode 21 has the thickness t larger in a central region corresponding to the central portion of the crystal piece 10 having high vibration energy than an outer region. As the thickness increases, the volume increases and the magnetic field formed by the coil portion 72 of the receiving coil 70 (an effect by the vibration of the upper excitation electrode 21 which is a magnetic material) is more affected. Since the vibration energy of the crystal piece 10 is higher in the central portion than the peripheral portions as described above, the thicker second magnetic portion 21a in the upper excitation electrode 21 is more greatly vibrated than the thinner first magnetic portion 21b. Accordingly, in the example illustrated in FIG. 6, the amplitude of the AC waveform generated in the receiving coil 70 may be efficiently increased, which may result in a high measurement precision of the oscillation frequency of the crystal unit 100.

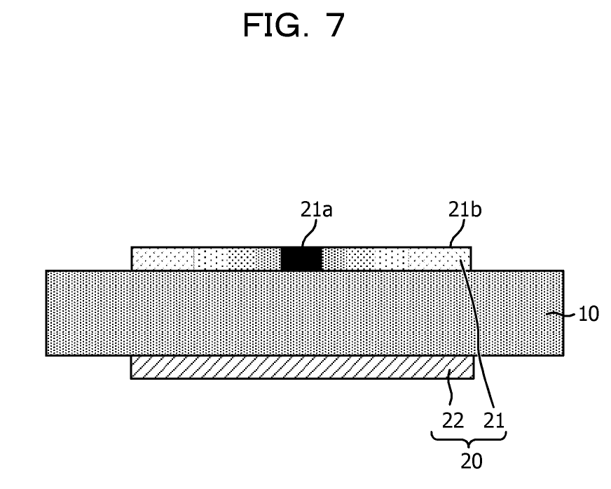

FIG. 7 is an explanatory view of another example of the upper excitation electrode 21, illustrating a sectional view of the upper excitation electrode 21, the crystal piece 10 and the lower excitation electrode 22. A cut section of the sectional view of FIG. 7 passes through the geometrical center (or the center of gravity) of the upper excitation electrode 21 when viewed from the top, in the same manner as in FIG. 6. In FIG. 7, the gray concentration in the upper excitation electrode 21 illustrates a density difference schematically, indicating that the darker gray forms higher density.

In the example illustrated in FIG. 7, the upper excitation electrode 21 includes a first magnetic portion 21b and a second magnetic portion 21a which is closer to the center side of the crystal piece 10 than the first magnetic portion 21b. The second magnetic portion 21a is denser than the first magnetic portion 21b. That is, in the example illustrated in FIG. 7, the upper excitation electrode 21 has a density larger (higher) in the central region than the outer region. In FIG. 7, the characteristics of this density may be characteristics corresponding to any section passing though the center of the upper excitation electrode 21. In the example illustrated in FIG. 7, the density is changed with five steps. An aspect of change in the density may be in multiple steps as illustrated in FIG. 7 or a smooth change aspect (mot step).

The density at each position in the upper excitation electrode 21 may be determined in such a manner to be proportional to the vibration energy at a corresponding position of the crystal piece 10 (e.g., a portion of the crystal piece 10 immediately below it). In an embodiment, the density of the upper excitation electrode 21 at a plurality of positions along a direction perpendicular to the thickness direction of the crystal piece 10 is proportional to the vibration energy in oscillation at each corresponding position of the crystal piece 10. The change in the density may be achieved by varying the content of magnetic material in the material of the upper excitation electrode 21.

According to the example illustrated in FIG. 7, the upper excitation electrode 21 has the density higher in a central region corresponding to the central portion of the crystal piece 10 having higher vibration energy than in an outer region. As the density becomes higher, the permeability increases and the magnetic field formed by the coil portion 72 of the receiving coil 70 (an effect by the vibration of the upper excitation electrode 21 which is a magnetic material) is more affected. Since the vibration energy of the crystal piece 10 is higher in the central portion than in the peripheral portions as described above, the second magnetic portion 21a having larger permeability in the upper excitation electrode 21 is more greatly vibrated than the first magnetic portion 21b having smaller permeability. Accordingly, in the example illustrated in FIG. 7, the amplitude of the AC waveform generated in the receiving coil 70 may be efficiently increased, which may result in a high measurement precision of the oscillation frequency of the crystal unit 100.

In addition, the example illustrated in FIG. 7 may be combined with the example illustrated in FIG. 6. For example, the upper excitation electrode 21 may be formed in such a manner that the second magnetic portion 21a is denser than the first magnetic portion 21b and the second magnetic portion 21a is thicker than the first magnetic portion 21b. In addition, the upper excitation electrode 21 may be made of a plurality of magnetic materials having different permeability in such a manner that the second magnetic portion 21a has higher permeability than the first magnetic portion 21b. This method may be used instead of or in addition to forming the upper excitation electrode 21 in such a manner that the second magnetic portion 21a is denser than the first magnetic portion 21b.

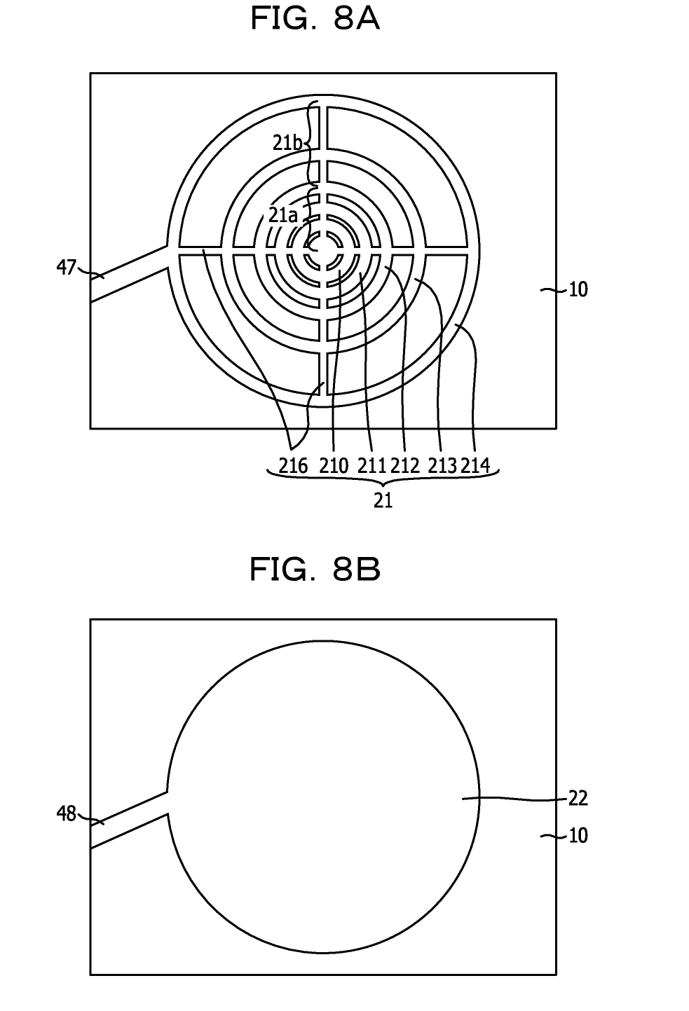

FIGS. 8A and 8B are explanatory views of another example of the upper excitation electrode 21, FIG. 8A being a top view of the upper excitation electrode 21 and FIG. 8B being a top view of the lower excitation electrode 22.

In the example illustrated in FIGS. 8A and 8B, the upper excitation electrode 21 includes a first magnetic portion 21b and a second magnetic portion 21a which is closer to the center side of the crystal piece 10 than the first magnetic portion 21b, and the second magnetic portion 21a is denser than the first magnetic portion 21b, in the same manner as the example illustrated in FIG. 7. That is, in the example illustrated in FIGS. 8A and 8B, the upper excitation electrode 21 has density larger (higher) in the central region than the outer region. In the example illustrated in FIGS. 8A and 8B, the upper excitation electrode 21 does not have the solid pattern as illustrated in the example illustrated in FIG. 7 but is formed with a pattern having a non-forming portion locally in a region facing the lower excitation electrode 22 (see, e.g., FIG. 8B).

That is, the upper excitation electrode 21 is formed over the entire region facing the lower excitation electrode 22 in the example illustrated in FIG. 7, whereas the upper excitation electrode 21 is partially formed over the region facing the lower excitation electrode 22 in the example illustrated in FIGS. 8A and 8B. At this time, the upper excitation electrode 21 is formed with a pattern to form high density in the central region than in the outer region. In the example illustrated in FIGS. 8A and 8B, the upper excitation electrode 21 has concentric circumferential patterns 210 to 214 and a connection pattern 216 connecting the circumferential patterns 210 to 214.

A gap in the radial direction between the circumferential patterns 210 to 214 is set to be smaller toward the center. That is, for example, a gap between the circumferential pattern 210 and the circumferential pattern 211 is smaller than a gap between the circumferential pattern 211 and the circumferential pattern 212, and the gap between the circumferential pattern 211 and the circumferential pattern 212 is smaller than a gap between the circumferential pattern 212 and the circumferential pattern 213. The connection pattern 216 extends in the radial direction with respect to the circumferential patterns 210 to 214 and connects the circumferential patterns 210 to 214.

According to the example illustrated in FIGS. 8A and 8B, the same effects as the example illustrated in FIG. 7 are achieved. In addition, according to the example illustrated in FIGS. 8A and 8B, the productivity may be improved since the change in the density is achieved by the film forming pattern.

Similarly, the example illustrated in FIGS. 8A and 8B may be combined with the example illustrated in FIG. 6. For example, the circumferential patterns 210 to 214 may be formed in such a manner that a pattern according to the second magnetic portion 21a is thicker than a pattern according to the first magnetic portion 21b. For example, the circumferential pattern 210 is thicker than circumferential pattern 211, and the circumferential pattern 211 is thicker than circumferential pattern 212. In addition, the circumferential patterns 210 to 214 may be formed with a plurality of magnetic materials having different permeability in such a manner that a pattern according to the second magnetic portion 21a has higher permeability than a pattern according to the first magnetic portion 21b. For example, the circumferential pattern 210 has higher permeability than the circumferential pattern 211, and the circumferential pattern 211 has higher permeability than the circumferential pattern 212.

In addition, in the above-described Embodiment 1, the upper excitation electrode 21 is made of conductive magnetic material such that it acts as an excitation electrode. Thus, since the upper excitation electrode 21 may have the transmission function of oscillation frequency information to the outside, as described above, in addition to the function as the excitation electrode, an efficient configuration may be achieved. However, as another embodiment, the upper excitation electrode 21 may be made of non-magnetic material and may have only the function as an excitation electrode.

For example, the upper excitation electrode 21 may be formed in the same aspect as the lower excitation electrode 22. In this case, a magnetic layer (another example of the magnetic portion) made of non-conductive magnetic material may be formed in the top or bottom surface of the upper excitation electrode 21 (e.g., between the bottom surface of the upper excitation electrode 21 and the crystal piece 10). Thus, the magnetic layer may have the transmission function of oscillation frequency information to the outside, as described above. In this case, the magnetic layer may have the same configuration as the above-described upper excitation electrode 21 except for material.

In addition, in the above-described Embodiment 1, the upper excitation electrode 21 is made of conductive magnetic material and the lower excitation electrode 22 is made of non-magnetic material. However, this may be reversed. That is, the upper excitation electrode 21 may be made of non-magnetic material and the lower excitation electrode 22 may be made of conductive magnetic material. In this case, in characteristic measurement, the receiving coil 70 may be disposed below the case 30.

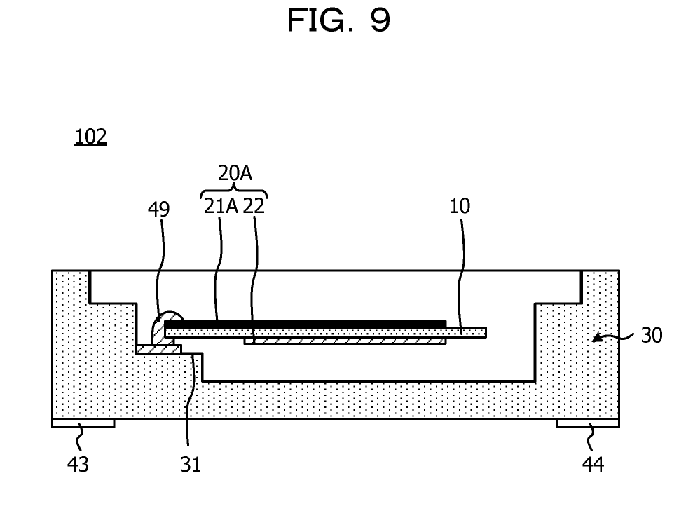

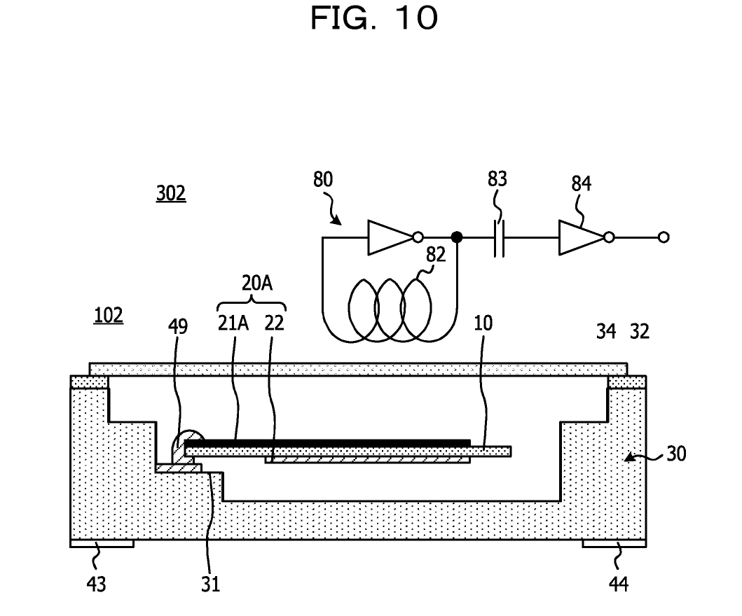

FIG. 9 is a schematic sectional view illustrating a crystal unit 102 according to one example (Embodiment 2). FIG. 9 illustrates a section corresponding to FIG. 1B. The crystal unit 102 according to Embodiment 2 is different from the crystal unit according to Embodiment 1 in that an upper excitation electrode 21A is replaced for the upper excitation electrode 21 of the above-described Embodiment 1. Other configurations of Embodiment 2 may be the same as the configurations of the above-described Embodiment 1 and therefore, explanation of which is not repeated, and are denoted by the same reference numerals in the drawings. FIG. 10 is a schematic view illustrating a characteristic measuring device 302 according to the crystal unit 102.

The crystal unit 102 includes a crystal piece 10, an excitation electrode 20A, a case 30 and external electrodes 41 to 44. The crystal unit 102 is of a surface mounting type as illustrated in FIGS. 1A and 1B.

The excitation electrode 21A includes an upper excitation electrode (one example of a magnet portion) and a lower excitation electrode 22.

The upper excitation electrode 21A is made of conductive magnetic material and is magnetized (residual-magnetized). That is, the upper excitation electrode 21A forms a permanent magnet. The upper excitation electrode 21A may be formed, for example, by magnetizing iron, nickel, or cobalt. The upper excitation electrode 21A may be formed in a film shape.

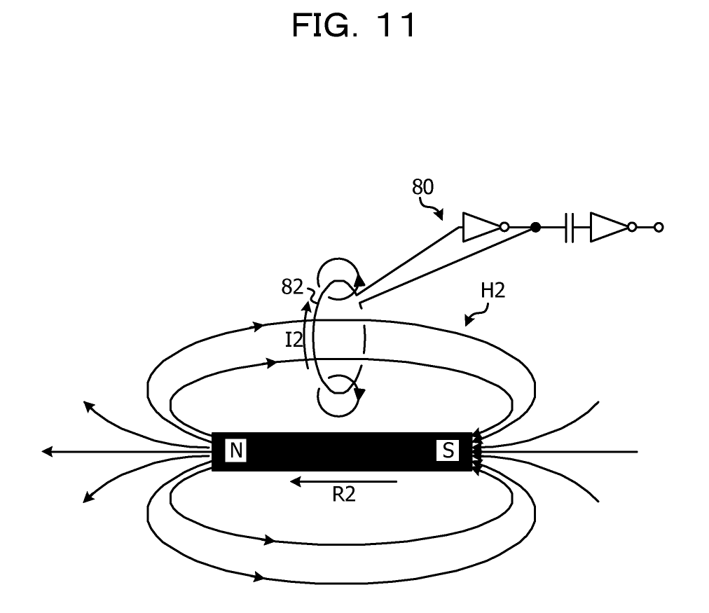

In operation of the crystal unit 102, when the crystal piece 10 is oscillated at a certain frequency, the upper excitation electrode 21A is vibrated at that frequency. At this time, as illustrated in FIG. 10, an AC waveform of a frequency corresponding to the oscillation frequency of the crystal piece 10 is generated in a receiving coil 80 disposed over the cover 34, due to the vibration of the upper excitation electrode 21. More specifically, in the example illustrated in FIG. 10, the upper excitation electrode 21A forms a permanent magnet and produces a magnetic field H2 as schematically illustrated in FIG. 11.

In addition, a magnetic flux passing through a coil portion 82 of the receiving coil 80 is formed. At this time, when the upper excitation electrode 21A is vibrated, the density of the magnetic flux passing through the coil portion 82 is periodically changed and an induced electromotive force is generated in the coil portion 82 by electromagnetic induction. For example, as schematically indicated by an arrow R2 in FIG. 11, when the upper excitation electrode 21A is displaced to the left side, an induced electromotive force is generated in the coil portion 82 in a direction against a change in the magnetic flux, and a current I2 by the induced electromotive force is generated in the coil portion 82. Similarly, when the upper excitation electrode 21A is displaced to the right side, a current (not illustrated) in the opposite direction to the current I2 is generated. In this manner, an AC waveform of a frequency corresponding to the oscillation frequency of the crystal piece 10 is generated in the receiving coil 80.

Accordingly, as schematically illustrated in FIG. 10, by forming the receiving coil 80 in the outside of the crystal unit 102 and generating this AC waveform in the receiving coil 80, it is possible to measure the oscillation frequency of the crystal unit 102. Hereinafter, the function to generate the AC waveform in the receiving coil 80 is also referred to as the function of transmission of oscillation frequency information to the outside. In addition, in the example illustrated in FIG. 10, a DC component of a received signal including the AC waveform generated in the coil portion 82 is cut by a capacitor 83 and an AC component thereof is amplified by an amplifier 84. Based on the amplified AC component, a frequency is measured (analyzed) by a measuring device such as, for example, an oscilloscope (not illustrated).

With the crystal unit 102 illustrated in FIG. 9, when the upper excitation electrode 21A of the crystal unit 102 includes the permanent magnet, the oscillation frequency of the crystal unit 102 may be externally measured. Thus, for example, for the crystal unit 102 in the mounted state, it is possible to measure the oscillation frequency. As the oscillation frequency may be measured, it becomes possible to make comparison of relative characteristics with non-defective products.

In the crystal unit 102, the upper excitation electrode 21A includes the permanent magnet and the lower excitation electrode 22 is made of non-magnetic material. This is because, for an AT cut type, the upper excitation electrode 21A and the lower excitation electrode 22 are opposite to each other in the vibration direction (e.g., vibrated in the reverse phase) and if the lower excitation electrode 22 also includes a permanent magnet, the AC waveform as described above is not formed in the receiving coil 80 by cancellation.

In the example illustrated in FIG. 10, in the characteristic measurement, the receiving coil 80 is disposed above the cover 34. However, the receiving coil 80 may be disposed at any positions as long as it is disposed relative to the crystal unit 102 in the aspect that the magnetic field passing through the coil portion 82 is formed by the upper excitation electrode 21A.

The configuration and effects of the crystal unit 100 described with reference to FIGS. 4 and 5 are equally applied to the crystal unit 102.

Next, several configuration examples of the upper excitation electrode 21A will be described.

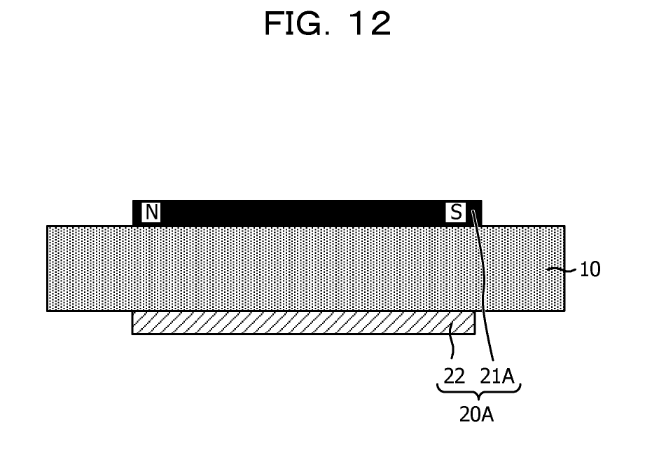

FIG. 12 is an explanatory view of one example of the upper excitation electrode 21A, illustrating a sectional view of the upper excitation electrode 21A, the crystal piece 10 and the lower excitation electrode 22. A cut section of the sectional view of FIG. 12 passes through the geometrical center (or the center of gravity) of the upper excitation electrode 21A when viewed from the top. For example, the cut section of the sectional view of FIG. 12 may be a vertical plane passing through the geometrical center of the upper excitation electrode 21A when viewed from the top.

In the example illustrated in FIG. 12, the upper excitation electrode 21A is entirely magnetized and is formed by a permanent magnet.

FIG. 13 is an explanatory view of another example of the upper excitation electrode 21A, illustrating a sectional view of the upper excitation electrode 21A, the crystal piece 10 and the lower excitation electrode 22. A cut section of the sectional view of FIG. 13 passes through the geometrical center (or the center of gravity) of the upper excitation electrode 21A when viewed from the top, in the same way as FIG. 12.

In the example illustrated in FIG. 13, the upper excitation electrode 21A is partially magnetized and is partially formed by a permanent magnet. More specifically, the upper excitation electrode 21A includes a magnetized central portion 210A and a non-magnetized peripheral portion 212A. The central portion 210A may be rectangular when viewed from the top.

According to the example illustrated in FIG. 13, the upper excitation electrode 21A has the magnetized central portion 210A in the central region corresponding to the central portion the crystal piece 10 having high vibration energy. Accordingly, the amplitude of the AC waveform generated in the receiving coil 80 may be efficiently increased, which may result in a high measurement precision of the oscillation frequency of the crystal unit 102.

In addition, in the above-described Embodiment 2, the upper excitation electrode 21A is made of conductive magnetic material such that it acts as an excitation electrode. Thus, since the upper excitation electrode 21A may have the transmission function of oscillation frequency information to the outside, as described above, in addition to the function as the excitation electrode, an efficient configuration may be achieved. However, as another embodiment, the upper excitation electrode 21A may be made of non-magnetic material and may have only the function as an excitation electrode.

For example, the upper excitation electrode 21A may be formed in the same aspect as the lower excitation electrode 22. In this case, a magnet layer (another example of the magnet portion) formed by magnetizing non-conductive magnetic material may be formed in the top or bottom surface of the upper excitation electrode 21A (e.g., between the bottom surface of the upper excitation electrode 21A and the crystal piece 10). Thus, the magnet layer may have the transmission function of oscillation frequency information to the outside, as described above. In this case, the magnet layer may have the same configuration as the above-described upper excitation electrode 21A except for the material.

In addition, in the above-described Embodiment 2, the upper excitation electrode 21A is formed by magnetizing conductive magnetic material and the lower excitation electrode 22 is made of non-magnetic material. However, this may be reversed. That is, the upper excitation electrode 21A may be made of non-magnetic material and the lower excitation electrode 22 may be formed by magnetizing conductive magnetic material. In this case, in characteristic measurement, the receiving coil 80 may be disposed below the case 30.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A crystal unit comprising:
a crystal piece;
a first excitation electrode disposed on a first surface of the crystal piece and made of non-magnetic material; and
a second excitation electrode disposed on a second surface in the opposite side to the first surface in the crystal piece facing the first excitation electrode, and made of magnetic material, the second excitation electrode includes a first magnetic portion and a second magnetic portion closer to the center of the crystal piece than the first magnetic portion,
wherein the second magnetic portion is larger than the first magnetic portion in terms of at least one of thickness, density and permeability.

2. The crystal unit according to claim 1, wherein
the second excitation electrode is made of conductive magnetic material.

3. The crystal unit according to claim 1, wherein
the second excitation electrode includes a permanent magnet.

4. The crystal unit according to claim 1, wherein
at least one of thickness, density and permeability of the second excitation electrode at a plurality of positions along a direction perpendicular to the thickness direction of the crystal piece is proportional to vibration energy in oscillation at each corresponding position of the crystal piece.

5. A crystal unit comprising:
a crystal piece;
a first excitation electrode disposed on a first surface of the crystal piece and made of non-magnetic material; and
a second excitation electrode disposed on a second surface in the opposite side to the first surface in the crystal piece facing the first excitation electrode, and made of magnetic material, the second excitation electrode includes a first magnetic portion formed for a first portion of the crystal piece; and a second magnetic portion formed for a second portion of the crystal piece having larger vibration energy in oscillation of the crystal piece than the first portion,
wherein the second magnetic portion is larger than the first magnetic portion in terms of at least one of thickness, density and permeability.

6. A device for measuring characteristics of a crystal unit, comprising:
a crystal piece;
a first excitation electrode disposed on a first surface of the crystal piece and made of non-magnetic material;
a second excitation electrode disposed on a second surface in the opposite side to the first surface in the crystal piece facing the first excitation electrode, and made of magnetic material; and
a receiving coil including a coil portion in which an AC waveform is generated by vibration of the second excitation electrode by which oscillation of the crystal piece is accompanied.

7. The device according to claim 6, wherein
the second excitation electrode is made of conductive material.

8. The device according to claim 7, wherein
the second excitation electrode includes a permanent magnet.
